(19) United States
(12) Patent Application Publication
(10) Pub. No.: US 2026/0092374 A1
(43) Pub. Date: Apr. 2, 2026

(54) SUBSTRATE PROCESSING APPARATUS AND OPERATING METHOD THEREOF

(71) Applicant: SAMSUNG ELECTRONICS CO., LTD., Suwon-si (KR)

(72) Inventors: Jong Hwan PARK, Suwon-si (KR); Dong Hyun KO, Suwon-si (KR); Yong Soon CHOI, Suwon-si (KR)

(73) Assignee: SAMSUNG ELECTRONICS CO., LTD., Suwon-si (KR)

(21) Appl. No.: 19/065,491

(22) Filed: Feb. 27, 2025

(30) Foreign Application Priority Data
Sep. 27, 2024 (KR) 10-2024-0131813

(51) Int. Cl. C23C 16/52; C23C 16/44; C23C 16/455

(52) U.S. Cl. CPC C23C 16/52; C23C 16/4408; C23C 16/4412; C23C 16/45523; C23C 16/45565; C23C 16/45597

(57) ABSTRACT

A substrate processing apparatus may include: a first showerhead that includes a first area, a second area, and a boundary area; a first gas supply configured to provide a first gas through the first area to the substrate, wherein the first gas is configured to form a tensile stress film; a second gas supply configured to provide a second gas through the second area to the substrate, wherein the second gas is configured to form a compressive stress film; a first purge gas supply configured to provide a first purge gas through the boundary area to the substrate; an exhaust configured to exhaust the first gas, the second gas, and the first purge gas through the boundary area; and a controller configured to perform control such that a supply of and the exhaust of the first gas, the second gas, and the first purge gas are simultaneously performed.

### CROSS-REFERENCE TO RELATED APPLICATION

This application claims priority to Korean Patent Application No. 10-2024-0131813, filed on Sep. 27, 2024 in the Korean Intellectual Property Office, and all the benefits accruing therefrom under 35 U.S.C. 119, the disclosure of which is herein incorporated by reference herein in its entirety.

### BACKGROUND

### 1. Field

The present disclosure relates to a substrate processing apparatus and an operating method thereof.

### 2. Description of Related Art

When various types of films are formed on a substrate, warpage of the substrate occurs depending on stress caused by the film. When the warpage is severe, it becomes difficult to perform a subsequent process. For example, it may be difficult to perform a photo process, an overlay may deteriorate, or arcing may occur due to poor chucking during a deposition process.

### SUMMARY

Provided is a substrate processing apparatus for simultaneously forming a tensile stress film and a compressive stress film on a rear surface of a substrate in order to compensate for warpage of the substrate.

Further, provided is a method for operating the substrate processing apparatus.

According to an aspect of the disclosure, a substrate processing apparatus includes: a chamber; a pedestal in the chamber and configured to support a substrate; a first showerhead in the chamber and configured to supply a plurality of gases to a rear surface of the substrate, wherein the first showerhead includes a first area, a second area, and a boundary area between the first area and the second area; a first gas supply configured to provide a first gas, among the plurality of gases, through the first area to the rear surface of the substrate, wherein the first gas is configured to form a tensile stress film on the rear surface of the substrate; a second gas supply configured to provide a second gas, among the plurality of gases, through the second area to the rear surface of the substrate, wherein the second gas is configured to form a compressive stress film on the rear surface of the substrate; a first purge gas supply configured to provide a first purge gas, among the plurality of gases, through the boundary area to the rear surface of the substrate; an exhaust configured to exhaust the first gas, the second gas, and the first purge gas through the boundary area; and a controller configured to control the first gas supply, the second gas supply, the first purge gas supply, and the exhaust, such that a supply of the first gas, the second gas, and the first purge gas and the exhaust of the first gas, the second gas, and the first purge gas are simultaneously performed, so that the tensile stress film and the compressive stress film are simultaneously formed on the rear surface of the substrate.

According to an aspect of the disclosure, a substrate processing apparatus includes: a chamber; a pedestal in the chamber and configured to support a substrate; a first showerhead in the chamber and configured to supply a plurality of gases to a rear surface of the substrate; a first gas supply configured to provide a first gas, among the plurality of gases, through the first showerhead to the rear surface of the substrate; a second gas supply configured to provide a second gas, among the plurality of gases, through the first showerhead to the rear surface of the substrate; a first purge gas supply configured to provide a first purge gas, among the plurality of gases, through the first showerhead to the rear surface of the substrate; and an exhaust connected to the first showerhead, wherein the first showerhead includes n equally-divided areas, and a boundary area between adjacent ones of the n equally-divided areas, wherein n is a natural number greater than or equal to 2, wherein each of the n equally-divided areas includes a center area, an edge area, and a sub-boundary area between the center area and the edge area, wherein the first gas supply is configured to supply the first gas through one from among the center area and the edge area of each of the n equally-divided areas, wherein the second gas supply is configured to supply the second gas through the other from among the center area and the edge area of each of the n equally-divided areas, wherein the first purge gas supply is configured to provide the first purge gas to the rear surface of the substrate through the boundary area and the sub-boundary area, wherein the exhaust is configured to exhaust the first gas, the second gas, and the first purge gas through the boundary area and the sub-boundary area.

According to an aspect of the disclosure, a method for operating a substrate processing apparatus includes: simultaneously forming a tensile stress film and a compressive stress film on a rear surface of a substrate, wherein the substrate is supported by a pedestal in a chamber of the substrate processing apparatus, wherein the simultaneously forming includes simultaneously: providing a first gas, for forming the tensile stress film on the rear surface of the substrate, through a first area of a first showerhead in the chamber, providing a second gas, for forming the compressive stress film on the rear surface of the substrate, through a second area of the first showerhead, providing a purge gas to the rear surface of the substrate through a boundary area of the first showerhead, the boundary area being between the first area and the second area, and exhausting the first gas, the second gas, and the purge gas through the boundary area.

Aspects and effects of embodiments of the disclosure are not limited to the aspects and effects mentioned above, and other aspects and effects not mentioned above may be clearly understood by those skilled in the art from descriptions as set forth below.

Specific details of the above and other example embodiments are included in the detailed description and drawings.

### BRIEF DESCRIPTION OF THE DRAWINGS

The above and other aspects and features of the disclosure will become more apparent by describing in detail non-limiting example embodiments thereof with reference to the attached drawings, in which:

FIG. 1 is a conceptual diagram illustrating a substrate processing apparatus according to one or more embodiments of the disclosure;

FIG. 2 is a perspective view illustrating a first showerhead illustrated in FIG. 1;

FIG. 3 is a diagram illustrating an area A of FIG. 2;

FIG. 4 is a diagram illustrating an operation of a substrate processing apparatus according to one or more embodiments of the disclosure;

FIG. 5 is a conceptual diagram illustrating a connection relationship between a gas supply device and the first showerhead in the substrate processing apparatus according to one or more embodiments of the disclosure;

FIG. 6 is a timing diagram illustrating a method for operating a substrate processing apparatus according to one or more embodiments of the disclosure;

FIGS. 7, 8, 9, and 10 are diagrams illustrating stress films formed on a rear surface of a substrate using the substrate processing apparatus according to one or more embodiments of the disclosure;

FIG. 11 is a conceptual diagram illustrating a connection relationship between the gas supply device and the first showerhead in the substrate processing apparatus according to one or more embodiments of the disclosure;

FIG. 12 is a timing diagram illustrating a method for operating a substrate processing apparatus according to one or more embodiments of the disclosure;

FIG. 13 is a diagram illustrating a stress film formed according to the method of FIG. 12; and

FIG. 14, 15, 16, and FIG. 17 are diagrams illustrating various example shapes of the first showerhead used in the substrate processing apparatus according to one or more embodiments of the disclosure.

### DETAILED DESCRIPTION

Although terms such as “first,” “second,” “upper,” and “lower” are used herein to describe various elements or components, these element or components are not limited by the terms. Rather, the terms are merely used herein to distinguish one element or component from another element or component. Therefore, a first element or component as mentioned below may also be a second element or component within the technical spirit of the disclosure. Further, a lower element or component as mentioned below may also be an upper element or component within the technical spirit of the disclosure.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, non-limiting example embodiments of the disclosure are described in detail with reference to the attached drawings. The same reference numerals are used for the same components in the drawings, and duplicate descriptions thereof may be omitted.

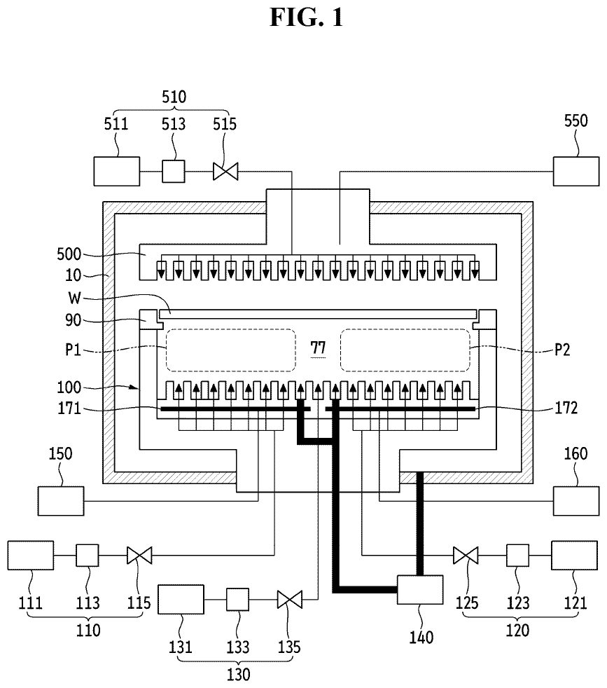

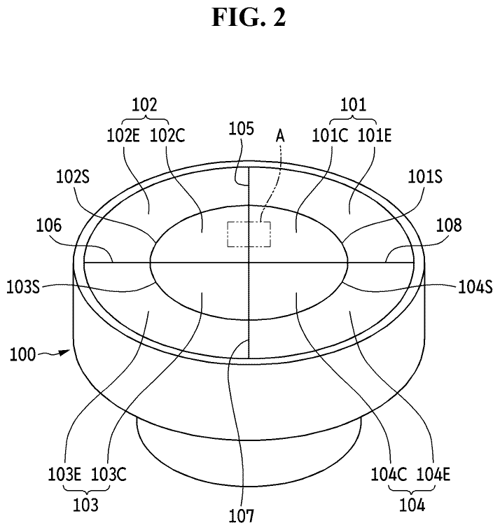

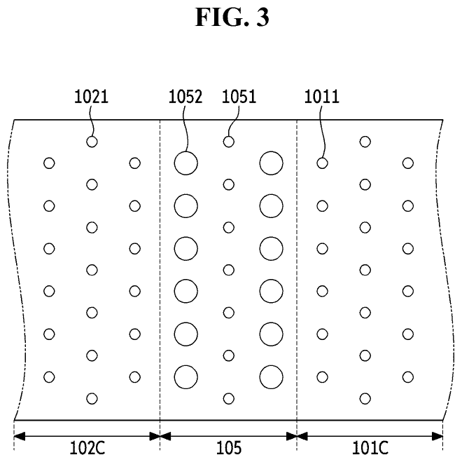

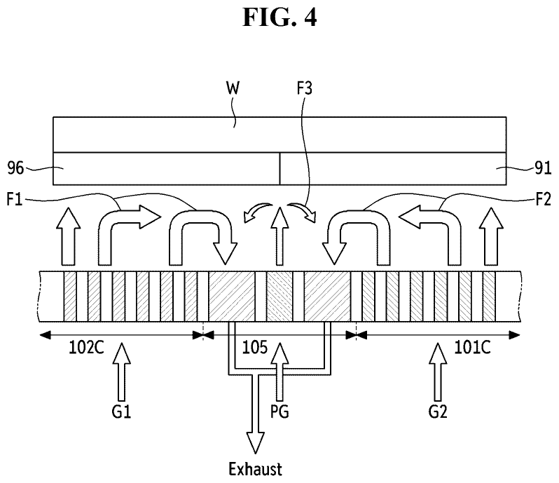

FIG. 1 is a conceptual diagram illustrating a substrate processing apparatus according to one or more embodiments of the disclosure. FIG. 2 is a perspective view illustrating a first showerhead illustrated in FIG. 1. FIG. 3 is a diagram illustrating an area A of FIG. 2. FIG. 4 is a diagram illustrating an operation of a substrate processing apparatus according to one or more embodiments of the disclosure.

First, referring to FIG. 1, the substrate processing apparatus according to one or more embodiments of the disclosure may be configured to simultaneously form a tensile stress film and a compressive stress film on a rear surface of a substrate W. For example, the tensile stress film may be a nitride film, and the compressive stress film may be an oxide film. In another example, both the tensile stress film and the compressive stress film may be nitride films, while a composition ratio of the nitride film used as the tensile stress film and a composition ratio of the nitride film used as the compressive stress film may be different from each other. The front and rear surfaces of the substrate W are opposite to each other. Various types of films, various elements, and/or metal wirings may be formed on the front surface (e.g., upper surface in FIG. 1) of the substrate W. Accordingly, warpage of the substrate W may occur in a comparative embodiment. In order to prevent this warpage, the tensile/compressive stress film may be formed on the rear surface (e.g., lower surface in FIG. 1) of the substrate W.

The substrate processing apparatus according to one or more embodiments of the disclosure may include a chamber 10, a pedestal 90, a first showerhead 100, a second showerhead 500, a first gas supply device 110 (e.g., a first gas supply), a second gas supply device 120 (e.g., a second gas supply), purge gas supply devices 130 and 510 (e.g., purge gas supplies), an exhaust device 140 (e.g., an exhaust), power sources 150, 160, and 550, etc. Each of the components (e.g., the chamber 10, the pedestal 90, the first showerhead 100, the second showerhead 500, the first gas supply device 110, the second gas supply device 120, the purge gas supply devices 130 and 510, the exhaust device 140, the power sources 150, 160, and 550, etc.) of the substrate processing apparatus may be controlled by a controller. The controller may be a part of, or separate from, the substrate processing apparatus. According to embodiments of the disclosure, the controller may include at least one processor, such as a central processing unit (CPU), a graphic processing unit (GPU), and/or another type of microprocessor, and an internal memory to perform functions of the controller described herein and/or other functions by loading corresponding computer code or instructions on the internal memory and execute the computer code or instructions.

The pedestal 90 may be installed in the chamber 10 and support the substrate W. The pedestal 90 may have a ring shape. However, embodiments of the disclosure are not limited thereto. The pedestal 90, which may be ring-shaped, may support an edge of the substrate W. In FIG. 1, the pedestal 90 is shown as being supported on and by the first showerhead 100. However, embodiments of the disclosure are not limited thereto.

The second showerhead 500 may be oriented to face the front surface (e.g., upper surface in FIG. 1) of the substrate W mounted on the pedestal 90.

The purge gas supply device 510 may provide purge gas through the second showerhead 500 toward the front surface (e.g., upper surface in FIG. 1) of the substrate W. The purge gas supply device 510 may include a tank 511 for storing therein the purge gas, a flow rate adjuster 513 for controlling a flow rate of the purge gas, and a valve 515 for selectively controlling whether to supply the purge gas. The purge gas may be an inert gas, and may be, for example, N₂ or Ar gas. However, embodiments of the disclosure are not limited thereto.

The purge gas provided to the front surface (e.g., upper surface in FIG. 1) of the substrate W through the second showerhead 500 may block first gas, second gas, or radical components sprayed through the first showerhead 100, thereby preventing formation of the compressive/tensile stress film on the front surface (e.g., upper surface in FIG. 1) of the substrate W.

Furthermore, the second showerhead 500 may be electrically connected to the power source 550. The power provided from the power source 550 may be used to generate plasma, and may have, for example, a high frequency (HF) band or a very high frequency (VHF) band.

The first showerhead 100 may be oriented to face the rear surface (e.g., lower surface in FIG. 1) of the substrate W mounted on the pedestal 90. A space 77 for performing a plasma process may be defined between the pedestal 90 and the first showerhead 100.

A plurality of lower electrodes 171 and 172 may be installed in the first showerhead 100. Each of the lower electrodes 171 and 172 may be installed in a corresponding area. For example, the lower electrode 171 may be installed in an area (e.g., area 102C) shown in FIG. 4, and the lower electrode 172 may be installed in another area (e.g., area 101C) shown in FIG. 4. The power sources 150 and 160 may be electrically connected to the plurality of lower electrodes 171 and 172, respectively. The power source 150 may provide first power to the lower electrode 171, while the power source 160 may provide second power to the lower electrode 172. The first power and the second power may be controlled (e.g., by the controller) independently of each other. The power provided from the power sources 150 and 160 may be used for bias. The power may have the LF (low frequency) band. The lower electrode(s) (e.g., lower electrodes 171 and 172) may control HF/VHF plasma generated between the substrate W and the first showerhead 100 using the LF bias, thereby inducing different ion bombardments. Accordingly, a difference between stress magnitudes of the thin films to be formed on the rear surface (e.g., lower surface in FIG. 1) of the substrate W may be maximized.

The first gas supply device 110 may provide the first gas toward the rear surface (e.g., lower surface in FIG. 1) of the substrate W through the first showerhead 100. The first gas supply device 110 may include a tank 111 for storing therein the first gas, a flow rate adjuster 113 for controlling a flow rate of the first gas, and a valve 115 for selectively controlling whether to supply the first gas.

The first gas may be a gas for forming the tensile stress film. The first gas may be a tensile precursor gas, and may be, for example, a gas for forming a nitride film.

The second gas supply device 120 may provide the second gas toward the rear surface (e.g., lower surface in FIG. 1) of the substrate W through the first showerhead 100. The second gas supply device 120 may include a tank 121 for storing therein the second gas, a flow rate adjuster 123 for controlling a flow rate of the second gas, and a valve 125 for selectively controlling whether to supply the second gas.

The second gas may be a gas for forming the compressive stress film. The second gas may be a compressive precursor gas, and may be, for example, a gas for forming an oxide film or a nitride film.

The purge gas supply device 130 may provide the purge gas toward the rear surface (e.g., lower surface in FIG. 1) of the substrate W through the first showerhead 100. The purge gas supply device 130 may include a tank 131 for storing therein the purge gas, a flow rate adjuster 133 for controlling a flow rate of the purge gas, and a valve 135 for selectively controlling whether to supply the purge gas. The purge gas may be an inert gas such as, for example, N₂, or Ar gas. However, embodiments of the disclosure are not limited thereto.

The exhaust device 140 may be connected to the first showerhead 100. Furthermore, the exhaust device 140 may be connected to a bottom of the chamber 10.

In this regard, referring to FIG. 2, the first showerhead 100 may include a plurality of areas 101, 102, 103, and 104, and respective boundary areas 105, 106, 107, and 108 between adjacent ones of the plurality of areas 101, 102, 103, and 104. The boundary area 105 may be located between the areas 101 and 102 that are adjacent to each other. The boundary area 106 may be located between the areas 102 and 103 that are adjacent to each other. The boundary area 107 may be located between the areas 103 and 104 that are adjacent to each other. The boundary area 108 may be located between the areas 101 and 104 that are adjacent to each other.

Specifically, each of the plurality of areas 101, 102, 103, and 104 may have various shapes. In one example, each of the plurality of areas 101, 102, 103, and 104 may be in a form of a quadrant, as illustrated in FIG. 2. That is, each of the plurality of areas 101, 102, 103, and 104 may have a fan shape having a central angle of 90 degrees around a center of the first showerhead 100.

Additionally, the area 101 may include a center area 101C, an edge area 101E, and a sub-boundary area 101S. In the first showerhead 100, the edge area 101E may be positioned outwardly of the center area 101C, and the sub-boundary area 101S may be disposed between the center area 101C and the edge area 101E. Similarly, the area 102 may include a center area 102C, an edge area 102E, and a sub-boundary area 102S. The area 103 may include a center area 103C, an edge area 103E, and a sub-boundary area 103S. The area 104 may include a center area 104C, an edge area 104E, and a sub-boundary area 104S.

A combination of the plurality of center areas 101C, 102C, 103C, and 104C may constitute a single circular shape. A combination of the plurality of edge areas 101E, 102E, 103E, and 104E may constitute a single donut shape.

In each of the plurality of areas 101, 102, 103, and 104, a plurality of holes may be installed for discharging a first gas or a second gas toward the rear surface (e.g., lower surface in FIG. 1) of the substrate W.

In each of the plurality of boundary areas 105, 106, 107, and 108, a plurality of holes may be defined for discharging the purge gas toward the rear surface (e.g., lower surface in FIG. 1) of the substrate W. In each of the plurality of boundary areas 105, 106, 107, and 108, a plurality of holes for exhausting the first gas, the second gas, and/or the purge gas may be defined.

For example, referring to FIG. 3, a plurality of holes 1011 may be defined in the center area 101C of the area 101, and a plurality of holes 1021 may be defined in the center area 102C of the area 102. In the boundary area 105, a plurality of holes 1051 for exhausting the purge gas and a plurality of holes 1052 for exhausting the gas may be defined.

Referring again to FIGS. 1-2, each of the plurality of areas 101, 102, 103, and 104 may be in fluid-communication with the first gas supply device 110 or the second gas supply device 120. For example, the area 101 may be in fluid-communication with the second gas supply device 120. The area 102 may be in fluid-communication with the first gas supply device 110, the area 103 may be in fluid-communication with the second gas supply device 120, and the area 104 may be in fluid-communication with the first gas supply device 110. Therefore, the second gas may be supplied toward the rear surface (e.g., lower surface in FIG. 1) of the substrate W through the areas 101 and 103. The first gas may be supplied toward the rear surface (e.g., lower surface in FIG. 1) of the substrate W through the areas 102 and 104.

The boundary areas 105, 106, 107, and 108 may be in fluid-communication with the purge gas supply device 130. Therefore, the purge gas may be supplied toward the rear surface (e.g., lower surface in FIG. 1) of the substrate W through the boundary areas 105, 106, 107, and 108.

In another example, the gas supply in the center area (e.g., e.g., center area 101C) and the gas supply in the edge area (e.g., the edge area 101E) of the area (e.g., the area 101) may be controlled (e.g., by the controller) to be different from each other. For example, the center area (e.g., the center area 101C) may be in fluid-communication with the second gas supply device 120, and the edge area (e.g., the edge area 101E) may be in fluid-communication with the first gas supply device 110. Alternatively, the first gas at a first flow rate may be supplied through the center area (e.g., the center area 101C), and the first gas at a second flow rate different from the first flow rate may be supplied through the edge area (e.g., the edge area 101E). Alternatively, the second gas at a third flow rate may be supplied through the center area (e.g., the center area 101C), and the second gas at a fourth flow rate different from the third flow rate may be supplied through the edge area (e.g., the edge area 101E).

Similarly, the gas supply in each of the respective center areas (e.g., the center areas 102C, 103C, and 104C) and each of the respective edge areas (e.g., the edge areas 102E, 103E, and 104E) of the other areas (e.g., the areas 102, 103, and 104) may be controlled (e.g., by the controller) to be different from each other.

In another example, the sub-boundary area (e.g., the sub-boundary area 101S) may be in fluid-communication with the purge gas supply device 130. Therefore, the purge gas may be supplied toward the rear surface (e.g., lower surface in FIG. 1) of the substrate W through the sub-boundary area (e.g., the sub-boundary area 101S). Similarly, each of the other sub-boundary areas (e.g., the sub-boundary areas 102S, 103S, and 104S) may be in fluid-communication with the purge gas supply device 130.

Hereinafter, referring to FIG. 4, simultaneous formation of a tensile stress film 96 and a compressive stress film 91 on the rear surface (e.g., lower surface in FIG. 1) of the substrate W will be described.

The first gas G1 may be supplied toward the rear surface (e.g., lower surface in FIG. 1) of the substrate W through the sub-area 102C.

The second gas G2 may be supplied toward the rear surface (e.g., lower surface in FIG. 1) of the substrate W through the sub-area 101C.

Through the boundary area 105, the purge gas PG may be supplied toward the rear surface (e.g., lower surface in FIG. 1) of the substrate W. Since the purge gas PG is injected from the boundary between the sub-area 102C and the sub-area 101C, a space 77 (see FIG. 1) between the substrate W and the first showerhead 100 may be divided into mutually spaced portions via the purge gas PG.

An electric field may be applied to the space 77 between the substrate W and the first showerhead 100. In a space vertically overlapping with the sub-area 102C, first plasma (e.g., first plasma P1 in FIG. 1) based on the first gas G1 may be generated. Furthermore, in a space vertically overlapping with the sub-area 101C, second plasma (e.g., second plasma P2 in FIG. 1) based on the second gas G2 may be generated. Due to the first plasma P1, the tensile stress film 96 may be deposited on the rear surface (e.g., lower surface in FIG. 1) of the substrate W. Due to the second plasma P2, the compressive stress film 91 may be deposited on the rear surface (e.g., lower surface in FIG. 1) of the substrate W.

Furthermore, since an exhaust operation is performed in the boundary area 105, the first gas G1, the second gas G2, and the purge gas PG may be exhausted (refer to reference arrows F1, F2, and F3). Furthermore, various components of the plasma may be exhausted in the boundary area 105.

In this way, due to the injection and exhaust operations of the purge gas PG in the boundary area 105, the space 77 between the substrate W and the first showerhead 100 may be divided into a plurality of spaces. Separate plasma may be generated in each divided space, and a planned stress film may be formed on a portion of the rear surface (e.g., lower surface in FIG. 1) of the substrate W corresponding to each divided space. In particular, stress films with different properties (e.g., the tensile stress film and the compressive stress film) may be simultaneously deposited on the rear surface (e.g., lower surface in FIG. 1) of the substrate W. Since the stress films with different properties may be simultaneously deposited thereon, a process time may be shortened.

Referring to FIG. 2, in the substrate processing apparatus according to one or more embodiments of the disclosure, an area of the first showerhead 100 may be divided into the plurality of areas (e.g., the areas 101, 102, 103, and 104) based on a film material to be deposited on the rear surface (e.g., lower surface in FIG. 1) of the substrate W. An individual gas supply line may be installed to each of the areas (e.g., the areas 101, 102, 103, and 104). Furthermore, an individual lower electrode (e.g., lower electrodes 171 and 172) may be installed in each of the areas (e.g., the areas 101, 102, 103, and 104). Furthermore, the purge gas may be injected and exhausted in each of the boundary areas (e.g., the boundary areas 105, 106, 107, and 108) so that individual deposition may be performed in each of the areas (e.g., the areas 101, 102, 103, and 104). Furthermore, while an appropriate stress film is formed in each of the plurality of areas (e.g., the areas 101, 102, 103, and 104) on the rear surface (e.g., lower surface in FIG. 1) of the substrate W, the purge gas may be discharged from the first showerhead 100 to the front surface (e.g., upper surface in FIG. 1) of the substrate W so that film deposition does not occur on the front surface (e.g., upper surface in FIG. 1) of the substrate W.

When a film material to be deposited on the rear surface (e.g., lower surface in FIG. 1) of the substrate W is controlled on a sub-area (e.g., the center area 101C, the edge area 101E, the center area 102C, the edge area 102E, the center area 103C, the edge area 103E, the center area 104C, and the edge area 104E) basis, an individual gas supply line may be installed at each of the sub-areas (e.g., the center area 101C, the edge area 101E, the center area 102C, the edge area 102E, the center area 103C, the edge area 103E, the center area 104C, and the edge area 104E). Furthermore, an individual lower electrode (e.g., the lower electrodes 171 and 172) may be installed in each of the sub-areas (e.g., the center area 101C, the edge area 101E, the center area 102C, the edge area 102E, the center area 103C, the edge area 103E, the center area 104C, and the edge area 104E). In order to enable individual deposition in each of the sub-areas (e.g., the center area 101C, the edge area 101E, the center area 102C, the edge area 102E, the center area 103C, the edge area 103E, the center area 104C, and the edge area 104E), the purge gas may be injected and exhausted in each of the boundary areas (e.g., the boundary areas 105, 106, 107, and 108) and each of the sub-boundary areas (e.g., the sub-boundary areas 101S, 102S, 103S, and 104S).

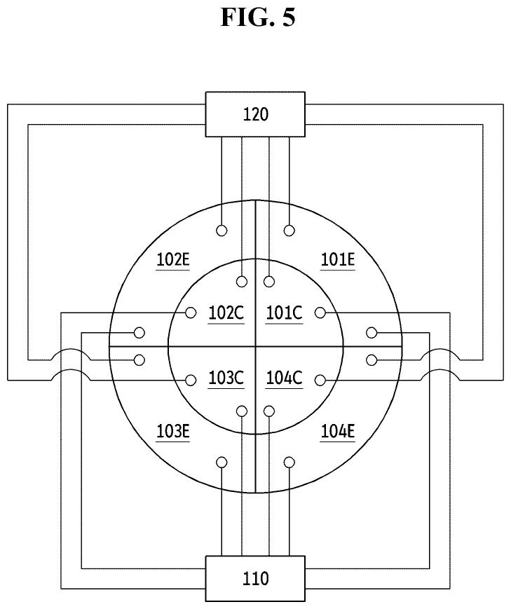

FIG. 5 is a conceptual diagram illustrating a connection relationship between the gas supply device and the first showerhead in the substrate processing apparatus according to one or more embodiments of the disclosure. For convenience of description, the connection relationship between the purge gas supply device and the first showerhead is not illustrated in FIG. 5.

Referring to FIG. 5, each of the plurality of sub-areas (e.g., the center area 101C, the edge area 101E, the center area 102C, the edge area 102E, the center area 103C, the edge area 103E, the center area 104C, and the edge area 104E) is connected to an individual gas supply line.

For example, each of the plurality of center areas 101C, 102C, 103C, and 104C may be connected to the first gas supply device 110 and the second gas supply device 120. Furthermore, each of the plurality of edge areas 101E, 102E, 103E, and 104E may be connected to the first gas supply device 110 and the second gas supply device 120.

With this configuration, the first gas or the second gas may be selectively injected toward the rear surface (e.g., lower surface in FIG. 1) of the substrate W in the sub-area (e.g., the center area 101C) depending on the embodiment. That is, depending on a zone where the tensile stress film is to be formed and a zone where the compressive stress film is to be formed on the rear surface (e.g., lower surface in FIG. 1) of the substrate W, a type of the gas to be injected through each of the plurality of sub-areas (e.g., the center area 101C, the edge area 101E, the center area 102C, the edge area 102E, the center area 103C, the edge area 103E, the center area 104C, and the edge area 104E) may be selected.

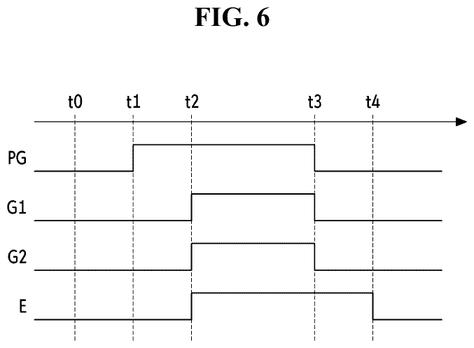

FIG. 6 is a timing diagram illustrating a method for operating a substrate processing apparatus according to one or more embodiments of the disclosure. For convenience of description, the following description focuses on differences from the descriptions given above with reference to FIG. 1 to FIG. 5.

Referring to FIG. 1, FIG. 2, and FIG. 6, at a time to, the substrate may be introduced into the chamber 10, and the substrate W may be seated on the pedestal 90.

At a time t1, the purge gas PG may be supplied into the chamber 10. For example, the purge gas supply device 130 may supply the purge gas PG into the chamber 10 through the first showerhead 100, and the purge gas supply device 510 may supply the purge gas PG into the chamber 10 through the second showerhead 500. As the purge gas PG is supplied into the chamber 10, an inside of the chamber 10 may become stabilized.

At a time t2, the first gas supply device 110 may supply the first gas G1, and the second gas supply device 120 may supply the second gas G2. An exhaust operation E may also proceed.

The first gas supply device 110 may supply the first gas G1 through areas (e.g., the areas 101 and 103) of the first showerhead 100, and the second gas supply device 120 may supply the second gas G2 through other areas (e.g., the areas 102 and 104) of the first showerhead 100. The areas (e.g., the areas 101 and 103) through which the first gas G1 is supplied and the areas (e.g., the areas 102 and 104) through which the second gas G2 is supplied may not overlap each other. The power source 550 may supply the power such that plasma (e.g., the first plasma P1 and the second plasma P2) are generated between the substrate W and the first showerhead 100. As described above, the adjacent plasmas (e.g., the first plasma P1 and the second plasma P2) are isolated from each other via the purge gas PG and under the exhaust operation E.

The tensile stress film may be formed on a portion of the rear surface (e.g., lower surface in FIG. 1) of the substrate W overlapping with areas (e.g., the areas 101 and 103) of the first showerhead 100 based on the plasma P1. The compressive stress film may be formed on a portion of the rear surface (e.g., lower surface in FIG. 1) of the substrate W overlapping with areas (e.g., the areas 102 and 104) of the second showerhead 500 based on the plasma P2.

At a time t3, the supply of the purge gas PG, the supply of the first gas G1, and the supply of the second gas G2 may be stopped.

Since the exhaust operation E may continue, various components of the first gas G1, the second gas G2, the purge gas PG, the first plasma P1, and the second plasma P2 may be exhausted from the inside of the chamber 10.

At a time t4, the exhaust operation E may be terminated. The substrate W may be discharged out of the chamber 10.

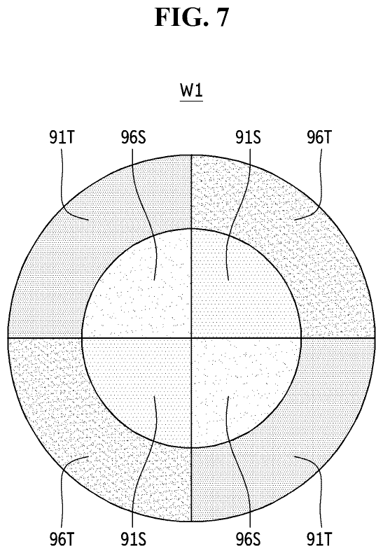

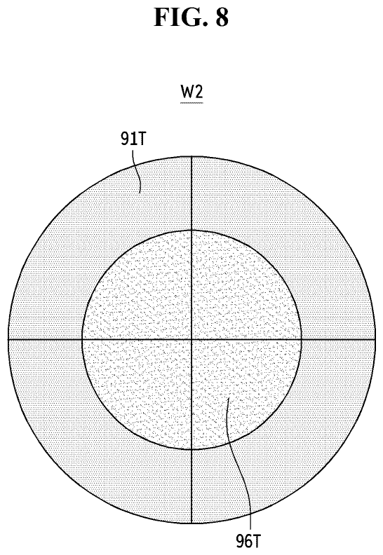

FIG. 7 to FIG. 10 are diagrams illustrating stress films formed on the rear surface of the substrate using the substrate processing apparatus according to one or more embodiments of the disclosure.

As described above with reference to FIG. 5, when the individual gas supply line has been connected to each of the plurality of sub-areas (e.g., the center area 101C, the edge area 101E, the center area 102C, the edge area 102E, the center area 103C, the edge area 103E, the center area 104C, and the edge area 104E) of the first showerhead 100, the first gas or the second gas may be selectively injected into each of the plurality of sub-areas (e.g., the center area 101C, the edge area 101E, the center area 102C, the edge area 102E, the center area 103C, the edge area 103E, the center area 104C, and the edge area 104E) depending on the embodiment.

Referring to FIG. 5 and FIG. 7, a first tensile stress film 96S may be formed on a portion of the rear surface (e.g., lower surface in FIG. 1) of the substrate W1 corresponding to or overlapping with sub-areas (e.g., the center areas 102C and 104C) of the first showerhead 100. A second tensile stress film 96T may be formed on a portion of the rear surface (e.g., lower surface in FIG. 1) of the substrate W1 corresponding to or overlapping with sub-areas (e.g., the edge areas 101E and 103E) of the first showerhead 100. The first tensile stress film 96S and the second tensile stress film 96T may provide stresses of different magnitudes from each other. This is because an amount of the first gas G1 provided through the center areas 102C and 104C and an amount of the first gas G1 provided through the edge areas 101E and 103E may be different from each other.

A first compressive stress film 91S may be formed on a portion of the rear surface (e.g., lower surface in FIG. 1) of the substrate W1 corresponding to or overlapping with sub-areas (e.g., the center areas 101C and 103C) of the first showerhead 100. A second compressive stress film 91T may be formed on a portion of the rear surface (e.g., lower surface in FIG. 1) of the substrate W1 corresponding to or overlapping with sub-areas (e.g., the edge areas 102E and 104E) of the first showerhead 100. The first compressive stress film 91S and the second compressive stress film 91T may provide stresses of different magnitudes from each other. This is because an amount of the second gas G2 provided through the center areas 101C and 103C and an amount of the second gas G2 provided through the edge areas 102E and 104E may be different from each other.

Referring to FIG. 5 and FIG. 8, a tensile stress film 96T may be formed on a portion of the rear surface (e.g., lower surface) of a substrate W2 corresponding to or overlapping with sub-areas (e.g., center areas 101C, 102C, 103C, and 104C) of the first showerhead 100. A compressive stress film 91T may be formed on a portion of the rear surface (e.g., lower surface in FIG. 1) of the substrate W2 corresponding to or overlapping with sub-areas (e.g., the edge areas 101E, 102E, 103E, and 104E) of the first showerhead 100.

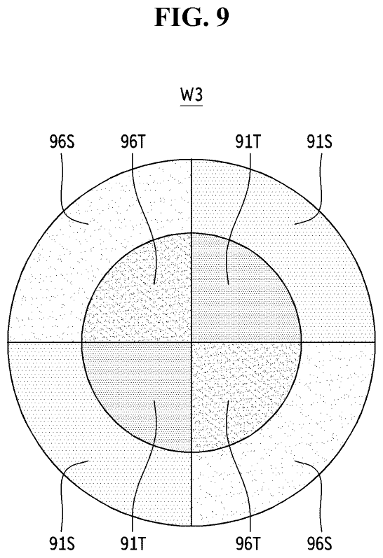

Referring to FIG. 5 and FIG. 9, a second tensile stress film 96T may be formed on a portion of the rear surface (e.g., lower surface) of a substrate W3 corresponding to or overlapping with sub-areas (e.g., the center areas 102C and 104C) of the first showerhead 100. A first tensile stress film 96S may be formed on a portion of the rear surface (e.g., lower surface in FIG. 1) of the substrate W3 corresponding to or overlapping with sub-areas (e.g., the edge areas 102E and 104E) of the first showerhead 100.

A second compressive stress film 91T may be formed on a portion of the rear surface (e.g., lower surface in FIG. 1) of the substrate W3 corresponding to or overlapping with sub-areas (e.g., the center areas 101C and 103C) of the first showerhead 100. A first compressive stress film 91S may be formed on a portion of the rear surface (e.g., lower surface in FIG. 1) of the substrate W1 corresponding to or overlapping with sub-areas (e.g., the edge areas 101E and 103E) of the first showerhead 100.

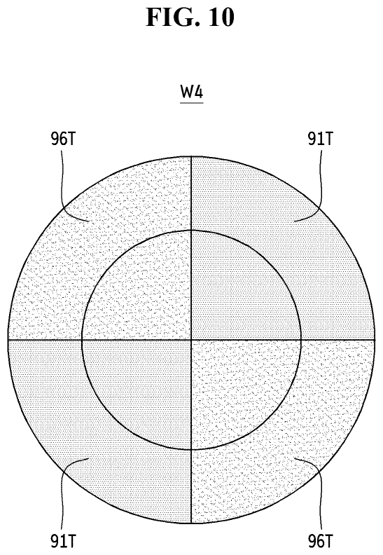

Referring to FIG. 5 and FIG. 10, a second tensile stress film 96T may be formed on a portion of the rear surface (e.g., lower surface) of a substrate W4 corresponding to or overlapping with areas (e.g., the areas 102 and 104) of the first showerhead 100. A second compressive stress film 91T may be formed on a portion of the rear surface (e.g., lower surface in FIG. 1) of the substrate W4 corresponding to or overlapping with areas (e.g., the areas 101 and 103) of the first showerhead 100.

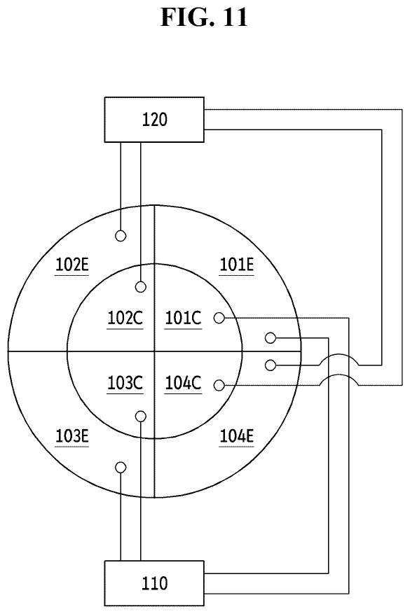

FIG. 11 is a conceptual diagram illustrating a connection relationship between the gas supply device and the first showerhead in the substrate processing apparatus according to one or more embodiments of the disclosure. For convenience of description, the connection relationship between the purge gas supply device and the first showerhead is not illustrated in FIG. 11.

Referring to FIG. 11, each of the plurality of sub-areas (e.g., the center area 101C, the edge area 101E, the center area 102C, the edge area 102E, the center area 103C, the edge area 103E, the center area 104C, and the edge area 104E) may be connected to an individual gas supply line.

For example, each of the center area 102C, the edge area 102E, the center area 104C, and the edge area 104E may be connected to the second gas supply device 120. Furthermore, each of the center area 101C, the edge area 101E, the center area 103C, and the edge area 103E may be connected to the first gas supply device 110.

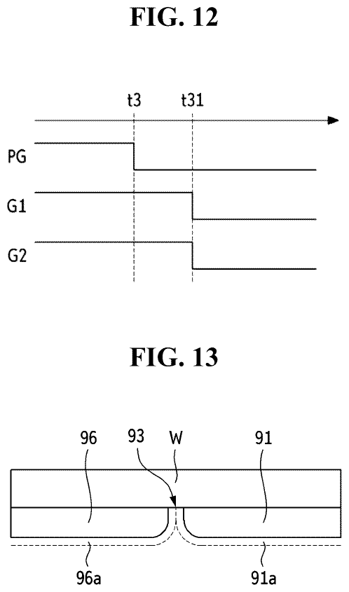

FIG. 12 is a timing diagram illustrating a method for operating a substrate processing apparatus according to one or more embodiments of the disclosure. FIG. 13 is a diagram illustrating a stress film formed according to the method of FIG. 12. For convenience of description, the description will focus on differences from the descriptions set forth above with reference to FIG. 6.

First, referring to FIG. 12, at a time t3, the supply of the purge gas PG may be stopped. Even when the supply of the purge gas PG is stopped, the supply of the first gas G1 and the second gas G2 may continue.

In this regard, referring to FIG. 13, at a time prior to the time t3, the stress film may not be formed on a portion 93 of the rear surface (e.g., lower surface in FIG. 1) of the substrate W due to the purge gas PG. The portion 93 may be located between the tensile stress film 96 and the compressive stress film 91.

Since the time t3, the supply of the purge gas PG is stopped, and the supply of the first gas G1 and the second gas G2 may continue, so that the tensile stress film 96a and the compressive stress film 91a may be deposited. Therefore, the tensile stress film 96a and the compressive stress film 91a may be deposited on the portion 93.

A period from the time t3 to the time t31 for which the purge gas PG supply may be stopped and the first gas G1 supply and the second gas G2 supply may be performed may be shorter than a period (refer to the time t2 to the time t3 in FIG. 6) for which the purge gas PG supply, the first gas G1 supply, and the second gas G2 supply may be performed simultaneously.

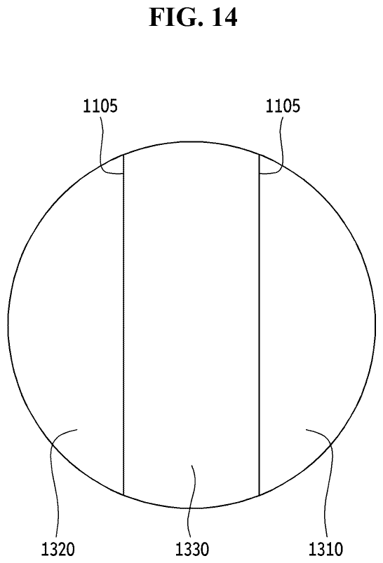

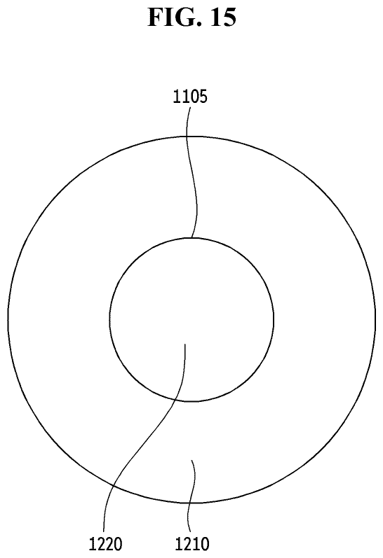

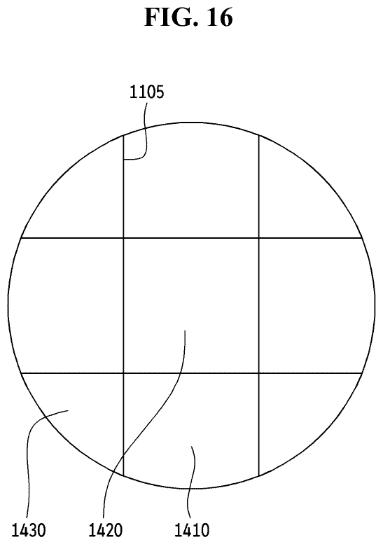

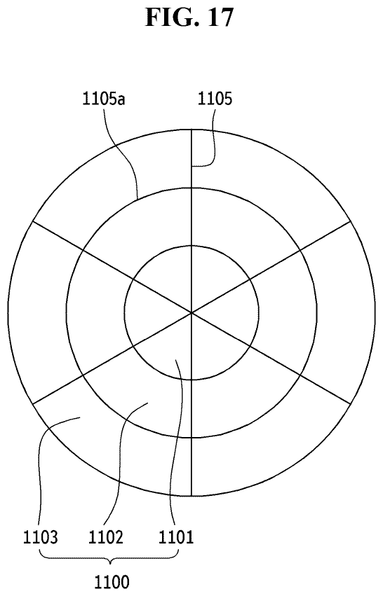

FIG. 14 to FIG. 17 are diagrams illustrating various example shapes of the first showerhead used in the substrate processing apparatus according to one or more embodiments of the disclosure.

Referring to FIG. 14, the first showerhead may include three areas 1310, 1320, and 1330 arranged adjacent to each other and extending in parallel with each other. A boundary area 1105 may be located between adjacent ones of the areas 1310, 1320, and 1330. The individual gas supply line may be connected to each of the areas 1310, 1320, and 1330. Therefore, various types of stress films may be formed on portions of the rear surface (e.g., lower surface in FIG. 1) of the substrate W corresponding to or overlapping with the areas 1310, 1320, and 1330, respectively.

Referring to FIG. 15, the first showerhead may include an area 1220 as a center area and a peripheral area 1210 disposed around the area 1220. The boundary area 1105 may be located between the area 1220 and the peripheral area 1210 that are adjacent to each other. An individual gas supply line may be connected to each of the area 1220 and the peripheral area 1210. Therefore, various types of stress films may be formed on portions of the rear surface (e.g., lower surface in FIG. 1) of the substrate W corresponding to or overlapping with the area 1220 and the peripheral area 1210, respectively.

Referring to FIG. 16, the first showerhead may include a plurality of areas 1410, 1420, and 1430 arranged in a matrix form. The boundary area 1105 may be located between adjacent ones of the areas 1410, 1420, and 1430. An individual gas supply line may be connected to each of the areas 1410, 1420, and 1430. Therefore, various types of stress films may be formed on portions of the rear surface (e.g., lower surface in FIG. 1) of the substrate W corresponding to or overlapping with the areas 1410, 1420, and 1430, respectively.

Referring to FIG. 17, the first showerhead may include six equally-divided areas 1100. Each of the six equally-divided areas 1100 may be fan-shaped with a central angle of 60 degrees around the center of the first showerhead. The boundary area 1105 may be located between adjacent ones of the six equally-divided areas 1100.

Each of the six equally-divided areas 1100 may include a plurality of sub-areas 1101, 1102, and 1103. A sub-boundary area 1105a may be located between adjacent ones of the sub-areas 1101, 1102, and 1103. A separate gas supply line may be connected to each of the sub-areas 1101, 1102, and 1103. Therefore, various types of stress films may be formed on portions of the rear surface (e.g., lower surface in FIG. 1) of the substrate W corresponding to or overlapping with the sub-areas 1101, 1102, and 1103, respectively.

In FIG. 17, the six equally-divided areas 1100 are illustrated. However, embodiments of the disclosure are not limited thereto. For example, the first showerhead may include n equally-divided areas (wherein n is a natural number greater than or equal to 2). Each of the n equally-divided areas may include a plurality of sub-areas (e.g., center area, edge area, etc.).

Although non-limiting example embodiments of the disclosure have been described with reference to the accompanying drawings, embodiments of the disclosure are not limited to the above example embodiments, and may be implemented in various different forms. A person skilled in the art may appreciate that embodiments of the disclosure may be practiced in other concrete forms without departing from the spirit and scope of the disclosure. Therefore, it should be appreciated that the example embodiments described above are not restrictive but illustrative in all respects.

What is claimed is:

1. A substrate processing apparatus comprising:
a chamber;
a pedestal in the chamber and configured to support a substrate;
a first showerhead in the chamber and configured to supply a plurality of gases to a rear surface of the substrate, wherein the first showerhead comprises a first area, a second area, and a boundary area between the first area and the second area;
a first gas supply configured to provide a first gas, among the plurality of gases, through the first area to the rear surface of the substrate, wherein the first gas is configured to form a tensile stress film on the rear surface of the substrate;
a second gas supply configured to provide a second gas, among the plurality of gases, through the second area to the rear surface of the substrate, wherein the second gas is configured to form a compressive stress film on the rear surface of the substrate;
a first purge gas supply configured to provide a first purge gas, among the plurality of gases, through the boundary area to the rear surface of the substrate;
an exhaust configured to exhaust the first gas, the second gas, and the first purge gas through the boundary area; and
a controller configured to control the first gas supply, the second gas supply, the first purge gas supply, and the exhaust, such that a supply of the first gas, the second gas, and the first purge gas and the exhaust of the first gas, the second gas, and the first purge gas are simultaneously performed, so that the tensile stress film and the compressive stress film are simultaneously formed on the rear surface of the substrate.

2. The substrate processing apparatus of claim 1, further comprising:
a first lower electrode in the first area;
a second lower electrode in the second area;
a first power source connected to the first lower electrode; and
a second power source connected to the second lower electrode.

3. The substrate processing apparatus of claim 2, wherein the first lower electrode is configured to generate a first plasma between the first area and the substrate, and the second lower electrode is configured to generate a second plasma between the second area and the substrate.

4. The substrate processing apparatus of claim 1, further comprising:
a second showerhead in the chamber and configured to supply a second purge gas to a front surface of the substrate; and
a second purge gas supply configured to provide the second purge gas through the second showerhead,
wherein the controller is further configured to control the second purge gas supply such that while the tensile stress film and the compressive stress film are simultaneously formed on the rear surface of the substrate, the second purge gas supply supplies the second purge gas to the front surface of the substrate.

5. The substrate processing apparatus of claim 1, wherein the controller is further configured to:
control the supply of the first gas, the second gas, and the first purge gas, and the exhaust of the first gas, the second gas, and the first purge gas to be simultaneously performed during a first time period,
control the supply of the first purge gas to be stopped and the supply of the first gas and the second gas to be maintained during a second time period subsequent to the first time period.

6. The substrate processing apparatus of claim 5, wherein the second time period is shorter than the first time period.

7. The substrate processing apparatus of claim 1, wherein the first area comprises:
a first sub-area configured to provide the first gas therethrough;
a second sub-area configured to provide the first gas therethrough; and
a first sub-boundary area between the first sub-area and the second sub-area,
wherein the first gas supply is configured to provide the first gas through the first sub-area and the second sub-area,
wherein the first purge gas supply is configured to provide the first purge gas through the first sub-boundary area, and
wherein the exhaust is configured to exhaust the first gas, the second gas, and the first purge gas through the first sub-boundary area.

8. The substrate processing apparatus of claim 7, wherein the first gas supply is configured to provide the first gas at a first flow rate through the first sub-area, and provide the first gas at a second flow rate through the second sub-area, wherein the first flow rate is different from the second flow rate.

9. The substrate processing apparatus of claim 1, wherein the rear surface of the substrate comprises a first zone and a second zone,
wherein the first zone overlaps with the first area of the first showerhead, and the second zone overlaps with the second area of the first showerhead, and
wherein the first gas is configured to form the tensile stress film on the first zone, and the second gas is configured to form the compressive stress film on the second zone.

10. A substrate processing apparatus comprising:
a chamber;
a pedestal in the chamber and configured to support a substrate;
a first showerhead in the chamber and configured to supply a plurality of gases to a rear surface of the substrate;
a first gas supply configured to provide a first gas, among the plurality of gases, through the first showerhead to the rear surface of the substrate;
a second gas supply configured to provide a second gas, among the plurality of gases, through the first showerhead to the rear surface of the substrate;
a first purge gas supply configured to provide a first purge gas, among the plurality of gases, through the first showerhead to the rear surface of the substrate; and
an exhaust connected to the first showerhead,
wherein the first showerhead comprises n equally-divided areas, and a boundary area between adjacent ones of the n equally-divided areas, wherein n is a natural number greater than or equal to 2,
wherein each of the n equally-divided areas comprises a center area, an edge area, and a sub-boundary area between the center area and the edge area,
wherein the first gas supply is configured to supply the first gas through one from among the center area and the edge area of each of the n equally-divided areas,
wherein the second gas supply is configured to supply the second gas through the other from among the center area and the edge area of each of the n equally-divided areas,
wherein the first purge gas supply is configured to provide the first purge gas to the rear surface of the substrate through the boundary area and the sub-boundary area, and
wherein the exhaust is configured to exhaust the first gas, the second gas, and the first purge gas through the boundary area and the sub-boundary area.

11. The substrate processing apparatus of claim 10, wherein the first gas is configured to form a tensile stress film, and the second gas is configured to form a compressive stress film, and
wherein the substrate processing apparatus further comprises a controller that is configured to control a supply of the first gas from the first gas supply and a supply of the second gas from the second gas supply to be simultaneously performed, such that the tensile stress film and the compressive stress film are simultaneously formed on the rear surface of the substrate.

12. The substrate processing apparatus of claim 10, further comprising:
a plurality of first lower electrodes in a plurality of center areas of the first showerhead, respectively;
a plurality of second lower electrodes in a plurality of edge areas of the first showerhead, respectively; and
a controller configured to independently control power supplied to each of the plurality of first lower electrodes, and independently control power supplied to each of the plurality of second lower electrodes.

13. The substrate processing apparatus of claim 12, wherein the plurality of first lower electrodes is configured to generate a first plasma between each of the plurality of center areas and the substrate, and
wherein the plurality of second lower electrodes is configured to generate a second plasma between each of the plurality of edge areas and the substrate.

14. The substrate processing apparatus of claim 10, further comprising:
a second showerhead in the chamber and configured to supply a second purge gas to a front surface of the substrate; and
a second purge gas supply configured to provide the second purge gas through the second showerhead.

15. A method for operating a substrate processing apparatus, the method comprising:
simultaneously forming a tensile stress film and a compressive stress film on a rear surface of a substrate, wherein the substrate is supported by a pedestal in a chamber of the substrate processing apparatus,
wherein the simultaneously forming comprises simultaneously:
providing a first gas, for forming the tensile stress film on the rear surface of the substrate, through a first area of a first showerhead in the chamber,
providing a second gas, for forming the compressive stress film on the rear surface of the substrate, through a second area of the first showerhead,
providing a purge gas to the rear surface of the substrate through a boundary area of the first showerhead, the boundary area being between the first area and the second area, and
exhausting the first gas, the second gas, and the purge gas through the boundary area.

16. The method of claim 15, wherein the substrate processing apparatus further includes a first lower electrode in the first area and a second lower electrode in the second area,
wherein the simultaneously forming further comprises independently controlling first power provided to the first lower electrode and second power provided to the second lower electrode.

17. The method of claim 15, further comprising supplying, by a second showerhead in the chamber, a second purge gas to a front surface of the substrate, while the tensile stress film and the compressive stress film are simultaneously formed on the rear surface of the substrate, so that the tensile stress film or the compressive stress film is not formed on the front surface of the substrate.

18. The method of claim 15, wherein the simultaneously forming comprises:
simultaneously performing, during a first time period, the providing the first gas, the providing the second gas, the providing the purge gas, and the exhausting; and
stopping the providing of the purge gas, while maintaining the providing of the first gas and the providing of the second gas, during a second time period subsequent to the first time period.

19. The method of claim 18, wherein the second time period is shorter than the first time period.

20. The method of claim 15, wherein the first area includes a first sub-area, a second sub-area, and a sub-boundary area between the first sub-area and the second sub-area,
wherein the providing the first gas comprises providing the first gas through the first sub-area and the second sub-area,
wherein the providing the purge gas comprises providing the purge gas through the sub-boundary area, and
wherein the exhausting comprises exhausting the first gas, the second gas, and the purge gas through the sub-boundary area.
